(19) United States
(12) Patent Application Publication
(10) Pub. No.: US 2019/0109029 A1
(43) Pub. Date: Apr. 11, 2019

(54) Methods, Apparatus and System for Dose Control for Semiconductor Wafer Processing

(71) Applicant: GLOBALFOUNDRIES INC., Grand Cayman (KY)

(72) Inventors: Eyup Cinar, Ballston Spa, NY (US); Robert Boyd Finlay, Ballston Lake, NY (US); Patrick Leonard Minton, Glens Falls, NY (US)

(73) Assignee: GLOBALFOUNDRIES INC., Grand Cayman (KY)

(21) Appl. No.: 15/726,359

(22) Filed: Oct. 5, 2017

(51) Int. Cl. H01L 21/67; H01L 21/02; G05B 13/02; H01L 21/66; G05B 19/418

(52) U.S. Cl. CPC H01L 21/67253; H01L 21/02008; H01L 22/26; H01L 22/12; G05B 19/41835; G05B 13/024

(57) ABSTRACT

At least one method, apparatus and system disclosed herein involves performing a wafer to wafer feedback control of process performed on a semiconductor substrate. A first process on a first semiconductor wafer of a run of semiconductor wafers is performed using a processing tool. A first gas analysis of a gas in the processing tool is performed upon performing the first process. Determining a process feedback adjustment based upon a result of the first gas analysis. Data relating to the process feedback adjustment is provided. Performing a second process on a second semiconductor wafer based on the data relating to the process feedback adjustment.

### BACKGROUND OF THE INVENTION

### Field of the Invention

Generally, the present disclosure relates to the manufacture of sophisticated semiconductor devices, and more specifically, to using wafer to wafer feedback for semiconductor wafer processing.

### Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a device that typically includes a source region, a drain region, a channel region that is positioned between the source region and the drain region, and a gate electrode positioned above the channel region.

In manufacturing FETs, whether planer FETs or finFETs, deposition of materials is an important part of such manufacturing process. More recently, atomic layer deposition (ALD) processes have been increasingly used to deposit met aerial onto semiconductor substrates. ALD processes are essentially a monolayer rate deposition processes. That is, a film is grown in stages, wherein each reactant type is pulsed onto a semiconductor wafer surface. Each of the reactant types are separated by a purge gas. Unlike previous deposition techniques, such as chemical vapor deposition (CVD), ALD techniques calls for each of the reactant types to chemically react with the surface of the wafer. Since this techniques is a monolayer process, the precision of the control of ALD processes is important.

As an etching process analog to ALD processes, designers have implemented atomic layer etching (ALE) processes. ALE processes have been increasingly replacing previous etching processes. ALE calls for a chemical precursor that is introduced upon the surface of the wafer. The chemical reactants are then removed from the process chamber. Subsequently, an energy source, such as low energy ion beams are introduced to induce a chemical reaction between the absorbed chemical and the wafer substrate. A thickness loss of a monolayer is experienced per cycle to perform the ALE process.

Some of the problems associated with the state of the art include the fact that ALD and ALE precursor gas dosage generally degrade over time. This may occur as a result of process disturbances, process drift, chemical level-changes in a vessel or chamber, etc. As a result, the dosage applied to one semiconductor wafer in a wafer-run or a wafer-lot may vary from the dosage applied to another wafer in that run/lot. This could lead to non-uniform deposition or etching results. Thus, layer thickness may vary from wafer to wafer when a run/lot of wafers are being processed. The problems with the state of the art may cause various defects, such as non-uniformity in wafer quality or performance, parasitic capacitance, non-uniform threshold voltages, etc.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system disclosed herein involves performing a wafer to wafer feedback control of process performed on a semiconductor substrate. A first process on a first semiconductor wafer of a run of semiconductor wafers is performed using a processing tool. A first gas analysis of a gas in the processing tool is performed upon performing the first process. Determining a process feedback adjustment based upon a result of the first gas analysis. Data relating to the process feedback adjustment is provided. Performing a second process on a second semiconductor wafer based on the data relating to the process feedback adjustment.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a process system for performing a wafer to wafer process feedback adjustment, in accordance with a first embodiment herein;

FIG. 2 illustrates a stylized block diagram depiction of a inner feedback process control loop embedded within an outer feedback process control loop, in accordance with embodiments herein;

FIG. 3 illustrates a stylized depiction of a dosage control system in accordance with embodiments herein;

FIG. 4 illustrated a stylized depiction of an exemplary gas pulse/purge cycle, in accordance with embodiments herein;

FIG. 5 illustrates a stylized depiction of a result of a gas analysis showing a spectrum intensity, in accordance with embodiments herein;

FIG. 6 illustrates a more detailed depiction of a system for using a gas analyzer, in accordance with embodiments herein; and

FIG. 7 illustrates a stylized flowchart depiction of performing a wafer to wafer control of semiconductor wafer processing, in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached Figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for performing a wafer to wafer feedback control of a deposition and/or an etch process performed on semiconductor wafers. Embodiments herein provide for utilizing a gas analyzer for acquiring data to perform a wafer to wafer feedback process adjustment during processing of semiconductor wafers. For example, a gas analyzer may be used to acquire feedback data relating to a fluid used for a deposition or an etch process for performing process adjustments in a wafer to wafer manner. Those skilled in the art would appreciate that the fluid may relate to a chemical in a gaseous form or in a liquid form.

As an exemplary embodiment, in an atomic layer deposition (ALD) process or in an atomic layer etch process (ALE), a precursor gas may be applied to a chamber or reactor. After a predetermined period of time, data relating to exhaust gas and/or residue precursor gas may be measured. Based on these measurements, a dosage adjustment of the precursor gas or another fluid may be performed in a wafer to wafer manner to provide a more consistent dosage application for the ALD and/or ALE processes across a plurality of wafers.

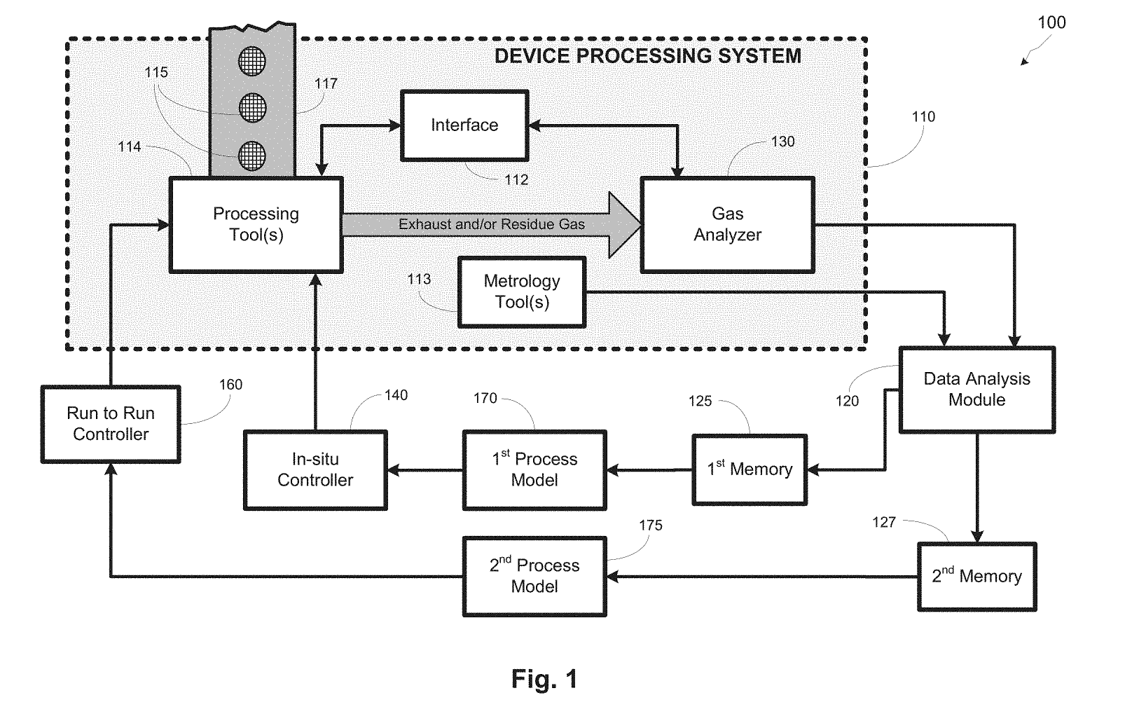

Turning now to FIG. 1, a stylized depiction of a process system for performing a wafer to wafer process feedback adjustment, in accordance with a first embodiment herein, is illustrated. A system 100 provides for utilizing a gas analyzer for acquiring data to perform a wafer to wafer feedback process-adjustment during processing of semiconductor wafers.

The system 100 of FIG. 1 may comprise a semiconductor device processing system 110 and various controllers described below. The semiconductor device processing system 110 may manufacture integrated circuit devices based upon data and/or instructions provided by an in-situ process controller 140 and/or a run to run controller 160. One or more of the processing steps performed by the processing system 110 may be controlled by the in-situ process controller 140 and/or the run to run controller 160. Each of the in-situ process controller 140 and the run to run controller 160 may be a workstation computer, a desktop computer, a laptop computer, a tablet computer, or any other type of computing device comprising one or more software products that are capable of controlling processes, receiving process feedback, receiving gas analysis data, performing learning cycle adjustments, performing process adjustments, etc.

The in-situ process controller 140 is capable of acquiring data between processing steps performed on semiconductor wafer with a “run” or a “lot” of wafers and making process adjustments on a wafer to wafer basis. The run to run controller 160 is capable of acquiring data between processing steps performed on a lot or run of semiconductor wafers, and controlling the operation of the system 110 on a run to run basis.

In some embodiments, the in-situ process controller 140 and the run to run controller 160 may act independently. In other embodiments, the in-situ controller 140 may provide a wafer to wafer feedback process adjustment, and substantially simultaneously, the run to run process controller 160 may provide a run to run feedback process adjustment.

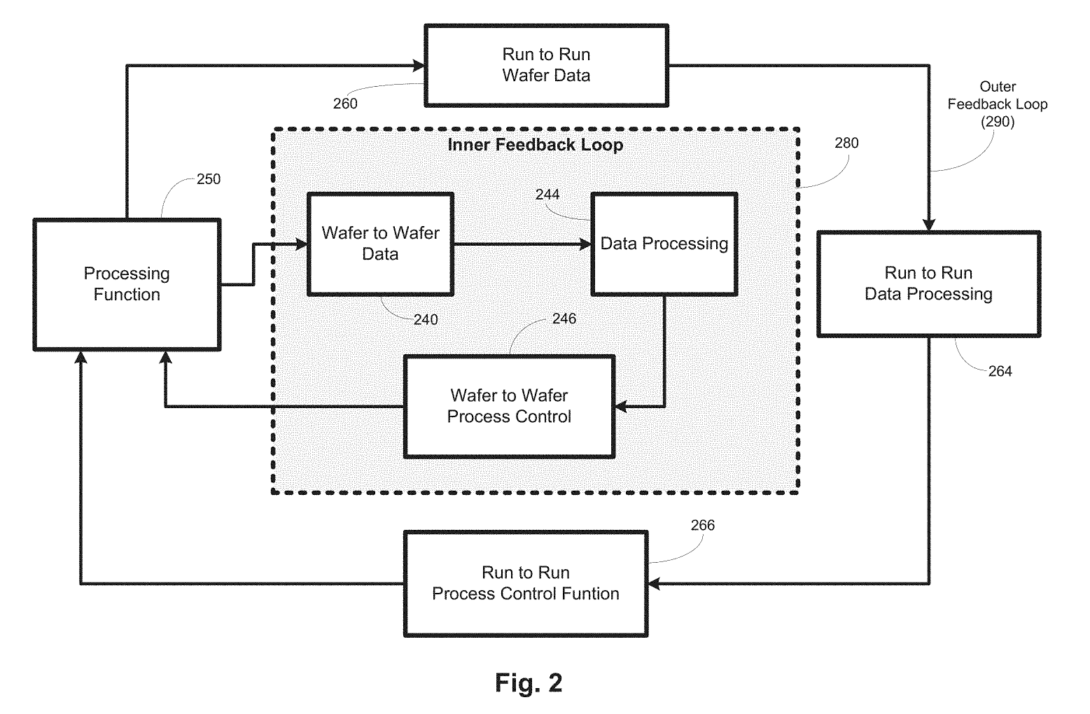

The in-situ controller 140 may be imbedded into an inner feedback loop, which is a wafer to wafer loop. The run to run controller 160 may be imbedded into an outer feedback loop, which is a run to run feedback loop. The inner and outer feedback loops are illustrated in FIG. 2. FIG. 2 illustrates a stylized block diagram depiction of an inner feedback process control loop embedded within an outer feedback process control loop, in accordance with embodiments herein.

Referring simultaneously to FIGS. 1 and 2, an inner feedback loop 280 and an outer feedback loop 290 are illustrated. A processing step may be performed, which is represented by the processing function block 250. Upon performing a processing function, wafer to wafer data (i.e., data from each wafer that is processed) 240 may be provided to a data processing function 244. The wafer to wafer data 240 may comprise gas analysis data. For example, exhaust measurements from a process chamber after providing a first precursor gas to perform an ALD or an ALE process, may be acquired. This data may provide an indication of the deposition or etch layer thickness. The data processing step may comprise acquiring wafer data, correlating the wafer data, and interpreting the wafer data.

Upon performing the data processing of block 244, the resultant information may be provided to a wafer to wafer process control function 246. The wafer to wafer process control function 246 may comprise adjusting one or more process parameter (e.g., dosage of the first precursor) for performing a process step on the next wafer in the process run (i.e., feedback to the processing function 250). Similarly, a wafer to wafer feedback process (i.e., the inner feedback loop 280) may be repeated for a second precursor gas, and so on.

FIG. 2 also exemplifies the outer feedback loop 290, which is a run to run feedback loop that uses the run to run process controller 160. Data collected from a processing of a plurality of wafers may be collected and stored, represented by the run to run wafer data (block 260). The run to run data 260 may be an aggregation of gas analysis data relating to performing an ALD or ALE process upon a plurality of wafers. For example, exhaust and/or residue gas measurements from a process chamber after providing the first precursor gas to perform an ALD or an ALE process, may be acquired. This data may provide an indication of the deposition or etch layer thickness relating to a plurality of wafers, e.g., all processed wafers in a wafer-run. The data processing step may comprise acquiring wafer data, correlating the wafer data to a particular wafer run, and interpreting the wafer data.

Upon performing the data processing of block 264, the resultant information may be provided to a run to run process control function 266. The run to run process control function 266 may comprise adjusting one or more process parameters (e.g., dosage of the first precursor) for performing a process step on the next run of wafers (i.e., feedback to the processing function 250). Similarly, a run to run feedback process (i.e., the outer feedback loop 290) may be repeated for an additional precursor gases. The feedback provided by the inner and outer feedback loops 280, 290 may include providing feedback control of temperature changes in the precursor gas of the processing tool for controlling the precursor material generation rate.

Continuing referring to FIG. 1, the semiconductor device processing system 110 may comprise additional metrology tools 113 in addition to the gas analyzer 130. In some embodiments, data from the additional metrology tools 113 may be used in conjunction with the data from the gas analyzer 130 to perform wafer to wafer feedback process adjustments and/or run to run feedback process adjustments.

The semiconductor device processing system 110 may also comprise an interface 112. The interface 112 may be operatively coupled to the various modules in the semiconductor device processing system 110 and provides a communication portal to those modules and other modules outside of the semiconductor device processing system 110. The communications facilitated by the interface 110 may include wired communication or wireless communications, e.g., Bluetooth™, WiFi, cellular, etc.

The system 100 may also comprise a data analysis module 120 which is capable of receiving data from the gas analyzer 130 and the metrology tools 113. Gas resulting from the processing steps performed by a processing tool 114 (e.g., exhaust gas and/or residue gas from ALD or ALE processes) is provided to the gas analyzer 130. The processing tool 114 may be an atomic layer process tool, e.g., an atomic layer deposition tool or an atomic layer etch tool.

The gas analyzer 130 is capable of analyzing and detecting various characteristics (e.g., chemical characteristics) of the gas received. The gas analyzer 130 is also capable of providing a signal indicative of the characteristic of the analyzed gas. The gas analyzer 130 may be a residual gas analyzer, a mass spectrometer, or the like.

The data analysis module 120 is capable of receiving an analog signal and converting the signal into a digital signal. The data analysis module 120 is capable of collecting metrology data, organizing/correlating the data, and providing the data to controllers. In some embodiments, the data analysis module 125 may convert gas exhaust data to layer thickness data relating to deposition layer or etch layer.

The data analysis module 125 is capable of storing wafer to wafer data into a 1^{st} memory 125. The data analysis module 125 is also capable of storing run to run data into a 2^{nd} memory 127. The 1^{st} and 2^{nd} memory units 125, 127 may be a hard drive memory, a non-volatile solid state memory (e.g., flash memory, DRAM memory, etc.), etc. In some embodiments, the 1^{st} and 2^{nd} memory units 125, 127 may be buffer memory units. In alternative embodiments, the 1^{st} and 2^{nd} memory units 125, 127 may be partitioned portions of a larger memory.

Data from the 1^{st} memory 125 may be provided to a 1^{st} process model 170. The 1^{st} process model 170 is capable of modeling the process operation on a wafer to wafer basis. Based on the data from the 1^{st} memory 125, the 1^{st} process model 170 may perform a modeling based on altered process parameters (e.g., dosage of a precursor). Data from the 1^{st} process model 170 may then be sent to the in-situ process controller 140, which may perform wafer to wafer process adjustments to the operations performed by the processing tools 114.

The processing tool(s) 114 may comprise a variety of process stations such as ALD tools, ALE tools, photolithography tools, deposition tools, etching tools, chemical-mechanical polishing (CMP) tools, etc. In one embodiment, the processing tool 114 is capable of performing an ALE process. In another embodiment, the processing tool 114 is capable of performing an ALD process, e.g., lanthanum oxide ALD process, a hafnium oxide ALD process, and/or other high-k oxide based ALD processes.

The processing tools 114 may be controlled by the in-situ process controller 140 and the run to run controller 160. The system 100 may provide semiconductor wafers 115 on a transport mechanism 117, such as a conveyor system. In some embodiments, the conveyor system may be sophisticated clean room transport systems that are capable of transporting semiconductor wafers.

Run to run data from the 2^{nd} memory 127 may be provided to a 2^{nd} process model 175. The 2^{nd} process model 175 is configured to model process operations on a run to run basis. Based on the data from the 2^{nd} memory 127, the 2^{nd} process model 175 may perform a modeling based on altered process parameters (e.g., dosage of a precursor) for a subsequent run of wafers. Data from the 2^{nd} process model 175 may then be sent to the run to run controller 160, which may perform run to run process adjustments to the operations performed by the processing tools 114.

The controllers 140, 160 may each be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The interface 112, the in-situ process controller 140, the data analysis module 120, the 1^{st} and 2^{nd} process models 170, 175, and/or the run to run process controller 160 may be hardware modules, software modules, firmware modules, and/or a combination thereof.

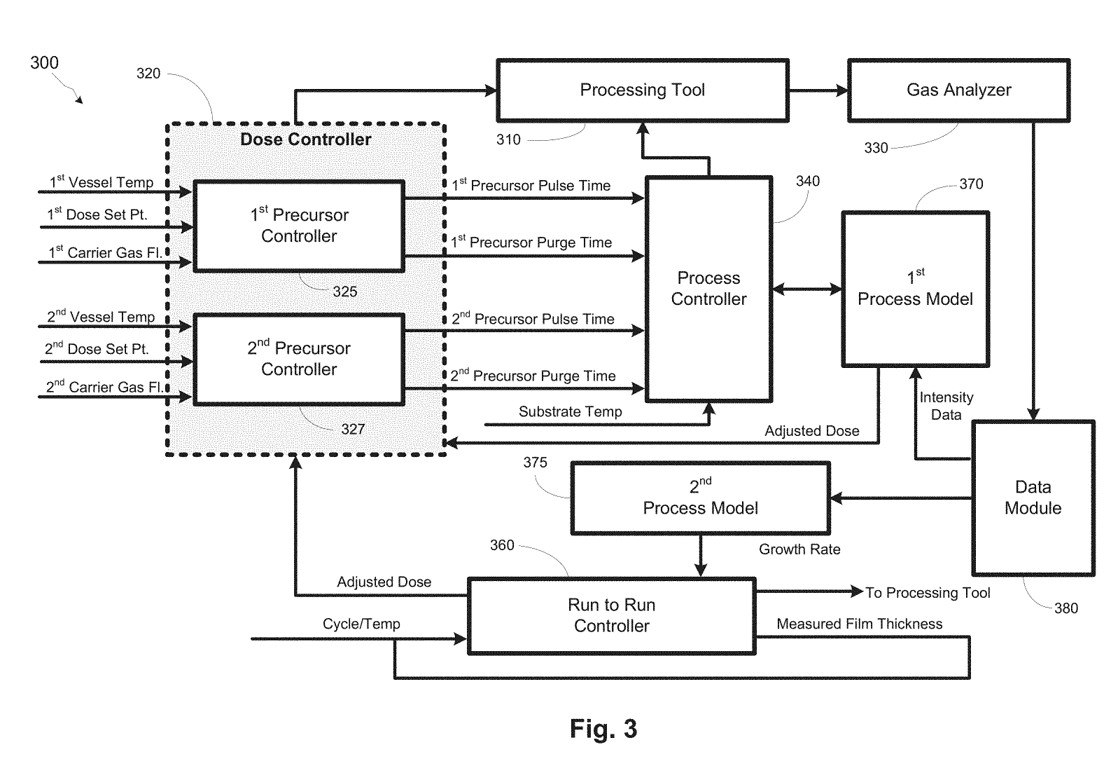

FIG. 3 illustrates a stylized depiction of a dosage control system in accordance with embodiments herein. A dosage control system 300 may be used to perform an ALD process and/or an ALE process. In one embodiment, a processing tool 310 is capable of performing an ALD process, while in another embodiment, the processing tool is configure to perform an ALE process. The processing tool 310 may receive various process parameters from a process controller 340. These parameters may include a 1^{st} precursor pulse time, a 1^{st} precursor purge time, 2^{nd} precursor pulse time, a 2^{nd} precursor purge time, and a substrate temperature parameter. The process controller 340 may also receive a substrate temperature parameter. The process controller 340 may then use these parameters to control the ALD and/or ALE processes performed by the processing tool.

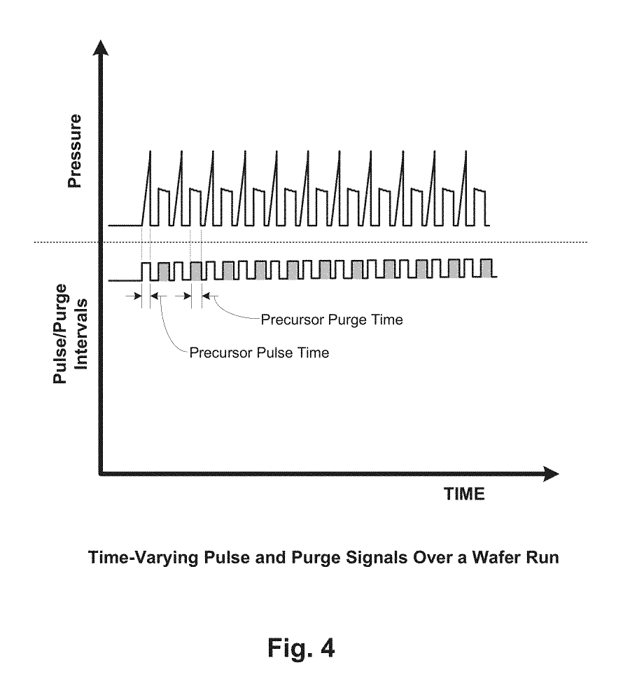

The precursor pulse time signal and the precursor purge time signal each may comprise “on” times and “off” times, denoting the pulses that correspond with delivery of precursor or purging of gases in the processing tool 310. The gas pressure moves up and down based on these “on” and “off” times of the pulse/purge cycles. FIG. 4 illustrates a stylized depiction of an exemplary set of gas pulse/purge cycles, in accordance with embodiments herein.

FIG. 4 depicts a time period during which a pulse of precursor gas may be delivered to a processing tool. A gas pressure signal may indicate that during the pulse, the gas pressure relating to the precursor gas spikes in the manner exemplified in FIG. 4. As shown in FIG. 4, the gas pressure goes down significantly at the end to the pulse time period. A purge time period may then follow, as indicated by the shaded pulse region in FIG. 4. At this time period, the gas pressure rises to a smaller degree, as compared to the pulse time period. The purge time period may be of a larger duration as compared to the pulse time period. For example, the pulse time period may be in the range of approximately 10 ms to less than about 120 sec and the purge time period may be in the range of about 10 ms to less than about 120 sec. The 1^{st} and 2^{nd} precursor pulse time signals and the 1^{st} and 2^{nd} purge time signals may follow a pattern similar to the depiction of FIG. 4. The number of pulse/purge cycles that are applied may be proportional to the dosage, i.e., the greater the number of pulse/purge cycles, the higher the dosage of the gas applied in an ALD and/or an ALE process.

Continuing referring to FIG. 3, the process controller 340 may receive the pulse time and purge time parameters from a dose controller 320. The dose controller 320 is adapted to generate the process parameters described above, which are sent to the process controller 340. The dose controller 320 may comprise a 1^{st} precursor controller 325 and a 2^{nd} precursor controller 327. Those skilled in the art having benefit of the present disclosure would appreciate that the dose controller 320 may comprise additional precursor controllers to provide pulse time and purge time parameters to the process controller 340.

The 1^{st} precursor controller 325 may receive a 1^{st} dosage set point, a 1^{st} vessel temperature signal, and a 1^{st} carrier gas flow signal to provide a precursor gas flow at a predetermined temperature. Similarly, the 2^{nd} precursor controller 325 may receive a 2^{nd} dosage set point, a 2^{nd} vessel temperature signal, and a 2^{nd} carrier gas flow signal. The precursor controllers are capable of using the dosage set point information, the vessel temperatures, and the carrier gas flow rates to provide the precursor pulse times and purge times to the process controller 340.

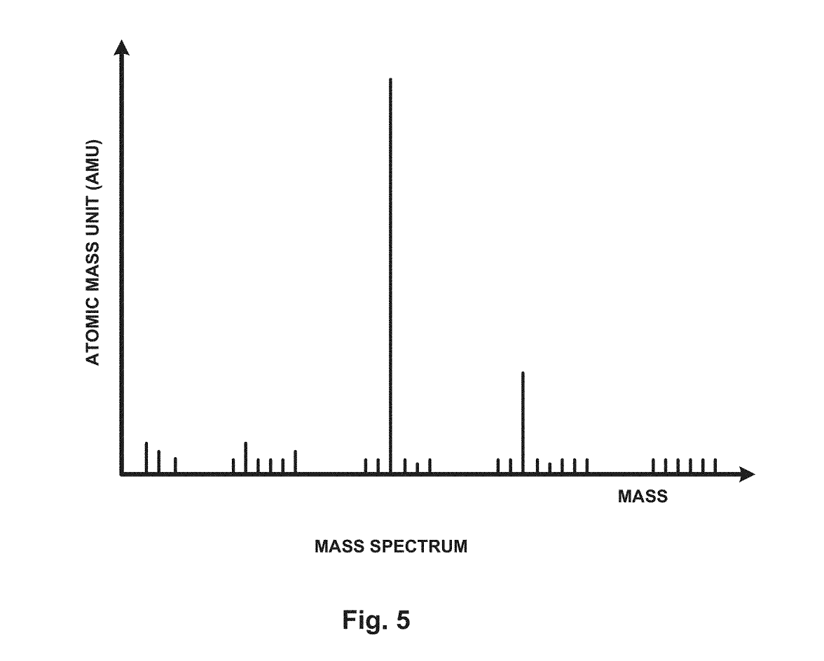

The system 300 also comprises a gas analyzer 330 that is capable of performing analysis of gas, e.g., exhaust and/or residue precursor gas, from the processing tool 310. In one example, the gas analyzer 330 may provide an output signal that comprises a mass spectrum intensity relative to atomic mass unit (AMU). FIG. 5 illustrates a stylized depiction of a result of a gas analysis showing spectrum intensity, in accordance with embodiments herein. The gas analyzer 330 may provide a signal that shows the intensity of the gas, e.g., N₂ or Ar of the exhaust gas from the processing tool 310. The intensity may correspond to the thickness of a layer. Based upon the intensity signal, the dosage applied to subsequent processes may be adjusted based on feedback changes in a wafer to wafer manner and/or in a run to run manner.

Continuing referring to FIG. 3, the system 300 may also comprise a data module 380 capable of receiving and processing data from the gas analyzer 330. The data module 380 is capable of collecting gas analysis data, organizing/correlating the data, and providing the data to process models. The data module 380 may comprise a plurality of memory portions capable of separately storing wafer to wafer gas analysis data on one memory portion, and storing run to run gas analysis data in another memory portion. In some embodiments, the data module 380 may convert gas exhaust data to layer thickness data relating to a deposition layer or an etch layer.

The system 300 also comprises a 1^{st} process model 370 that is capable of providing process adjustment data to the dose controller 320 based upon gas analysis data from the data module 380. The 1^{st} process model may receive intensity data relating to the 1^{st} precursor and an intensity data relating to the 2^{nd} precursor. The 1^{st} process model 370 is configured to provide feedback adjustment on a wafer to wafer basis based on process modeling performed using gas analysis data from the data module 380. The 1^{st} process model 370 may provide a feedback signal comprising adjusted dosage to the dose controller 320 on a wafer to wafer basis.

The system also comprises a 2^{nd} process model 375, which also receives data from the data module 380. The 2^{nd} process model 375 is capable of collecting gas analysis data relating to a plurality of wafer, e.g., a run of wafers, and determining a layer growth rate for an ALD process, and an etch rate for an ALE process. That is, various intensity data from the gas analyzer 330 may be compared and a rate of layer growth (ALD process) or a rate of layer decline (ALE process) may be determined for a plurality of semiconductor wafers.

The system comprises a run to run controller 360, which may be capable of receiving growth rate (for an ALD process) and/or layer declining rate (for an ALE process) from the 2^{nd} process model. Based on the layer-growth rate or a layer-decline rate, the run to run controller 360 may provide feedback to perform process adjustments (e.g., dosage changes, etc.). The run to run controller 360 may adjust the cycle or temperature based on measured film thickness and data from the 2^{nd} process model 375. A signal comprising run to run process adjustments may be provided to the processing tool 310 for performing run to run process control adjustment. In some embodiments, the 2^{nd} process model 375 may also provide a feedback signal comprising adjusted dosage to the dose controller 320 on a run to run basis.

In some embodiments, the interaction between the run to run controller 360 and the dosage controller 320 may provide a supervisory function in performing ALD and/or ALE processes. The run to run controller 360 and the dosage controller 320 may be used to perform a prediction function for predicting film growth rates for the run to run controller 360. This prediction function may be used to perform feedback adjustment for subsequent run of wafers.

In some embodiments, the 1^{st} and 2^{nd} process models 370, 375 comprise a calibration look-up table that may be used to perform a correlation between the dosage for an ALD or ALE process and the linear atomic mass unit intensity measurement and/or the sum of the linear sum of all measured liner atomic mass unit intensity measurements. These atomic mass unit intensity measurements may be used to determine a film thickness and/or film thickness growth rate, which in turn, may be used to perform feedback adjustments, e.g., run to run feedback adjustments.

The dose controller 320, process controller 340, the 1^{st} process model 370, the data module 380, the 2^{nd} process model 375, and/or the run to run controller 360 may be hardware devices, software devices, and/or firmware devices.

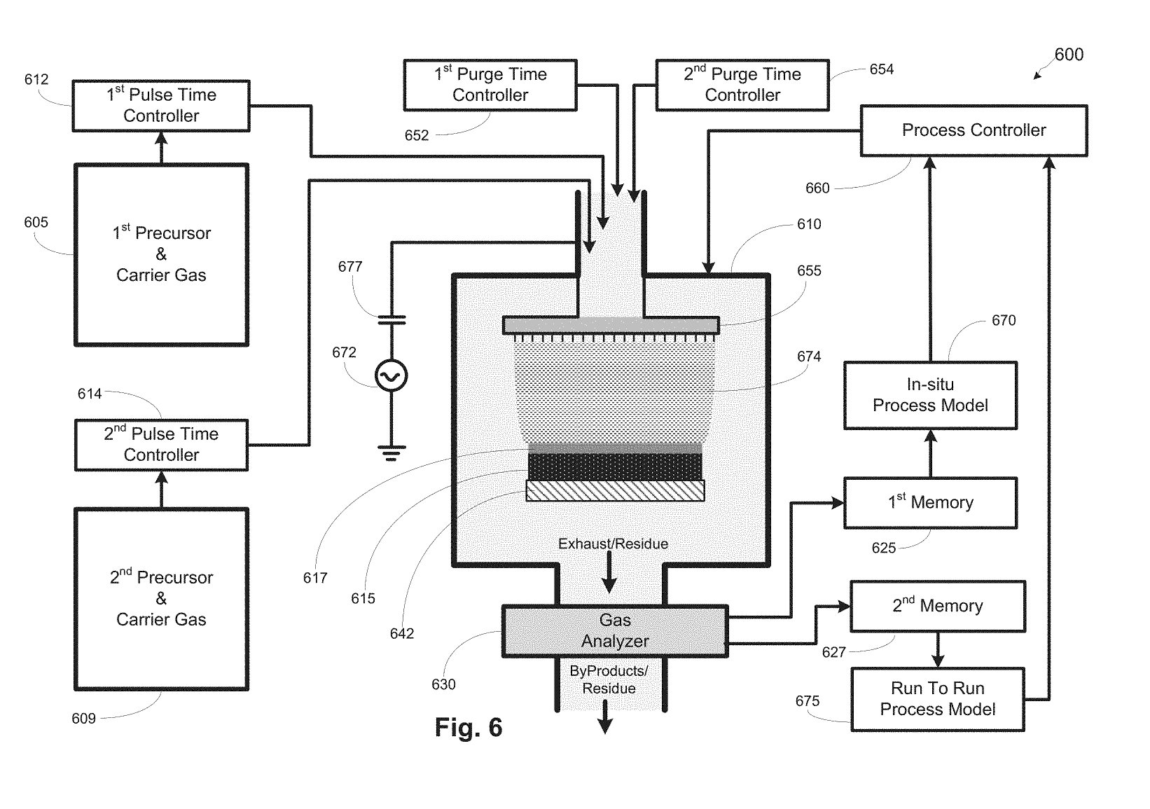

FIG. 6 illustrates a more detailed depiction of a system for using a gas analyzer, in accordance with embodiments herein. A system 600 may comprise a 1^{st} vessel 605 comprising a 1^{st} precursor and a carrier gas (e.g., N₂). The 1^{st} vessel 605 may be initially brought to a 1^{st} temperature. The system 600 may also comprise a 2^{nd} vessel 609 comprising a 2^{nd} precursor and a carrier gas. The 2^{nd} vessel 609 may be initially brought to a 2^{nd} temperature.

The system 600 comprises a reactor 610 that is capable of facilitating an ALD process, and in another embodiment, an ALE process. A voltage source 672 and a capacitive unit 677 in series with the voltage source 672 may provide a power supply to the reactor 610. The reactor 610 is capable of performing a deposition process or an etch process on a substrate 615. The reactor 610 comprises an electrode 655, which may comprise a plurality of openings comparable to a shower head. The electrode 655 is capable of directing precursor gas 674 onto the surface of a substrate 615. A precursor is charged and provided to the substrate 615 by the electrode 655. A heater 642 may provide a predetermined amount of heat to the substrate 615. This reaction forms a film layer 617.

A pulse/purge cycle may be used to deliver the 1^{st} and 2^{nd} precursors to the reactor 610. A 1^{st} pulse time controller 612 provides a pulse of the 1^{st} precursor to the reactor 610. A 1^{st} purge controller 652 performs a purge of the 1^{st} precursor in the reactor. Similarly, a 2^{nd} pulse time controller 614 provides a pulse of the 2^{nd} precursor to the reactor 610. A 2^{nd} purge controller 654 performs a purge of the 2^{nd} precursor in the reactor. These pulse/purge cycles may be repeated until a desired film thickness is achieved.

The 1^{st} pulse time controller 612, the 1^{st} purge time controller 652, the 2^{nd} pulse time controller 614, the 2^{nd} purge time controller may each comprise a valve to control gas flow, wherein the valves may be electrically controlled.

A process controller 660 is capable of controlling the dosage of the precursors by controlling the 1^{st} and 2^{nd} pulse time controllers 612, 614, and the 1^{st} and 2^{nd} purge time controllers 652, 654. In some embodiments, process controller 660 may also control the heater 642, voltage source 672, 1^{st} and 2^{nd} vessel temperatures, and/or other parameters that control the operations of the reactor 610.

Exhaust from the reactor 610 may be provided to a gas analyzer 630. The gas analyzed by the gas analyzer 630 may be process byproducts and/or left over precursor gas. The gas analyzer 630 may provide wafer to wafer data (i.e., data relating to individual wafers) to a 1^{st} memory unit 625. The gas analyzer 630 may provide run to run data (i.e., data relating to a plurality or run of wafers) to a 2^{nd} memory unit 627. The 1^{st} and 2^{nd} memory units 625, 627 may be buffer memory units.

Data from the 1^{st} memory unit 625 may be provided to an in-situ process model 670. The in-situ process model 670 is capable of modeling the process operation on a wafer to wafer basis. Based on the data from the 1^{st} memory unit 625, the in-situ process model 670 may perform a modeling based on altered process parameters (e.g., dosage of a precursor). Data from the 1^{st} process model 670 may then be sent to the process controller 670, which may perform wafer to wafer process adjustments to the operations performed by the system 600.

Data from the 2^{nd} memory unit 627 may be provided to a run to run process model 675. The run to run process model 675 is capable of modeling the process operation on a run to run basis. Based on the data from the 2^{nd} memory unit 627, the run to run process model 675 may perform a modeling process based on altered process parameters (e.g., dosage of a precursor). Data from the 2^{nd} process model 675 (e.g., film thickness growth rate) may then be sent to the process controller 670, which may perform run to run process adjustments to the operations performed by the system 600.

In alternative embodiments, the in-situ process model 670 and the run to run process model 675 may be part of the process controller 660. The process controller 660, the in-situ process model 670, and/or the run to run process model 675 may be hardware devices, software devices, and/or firmware devices.

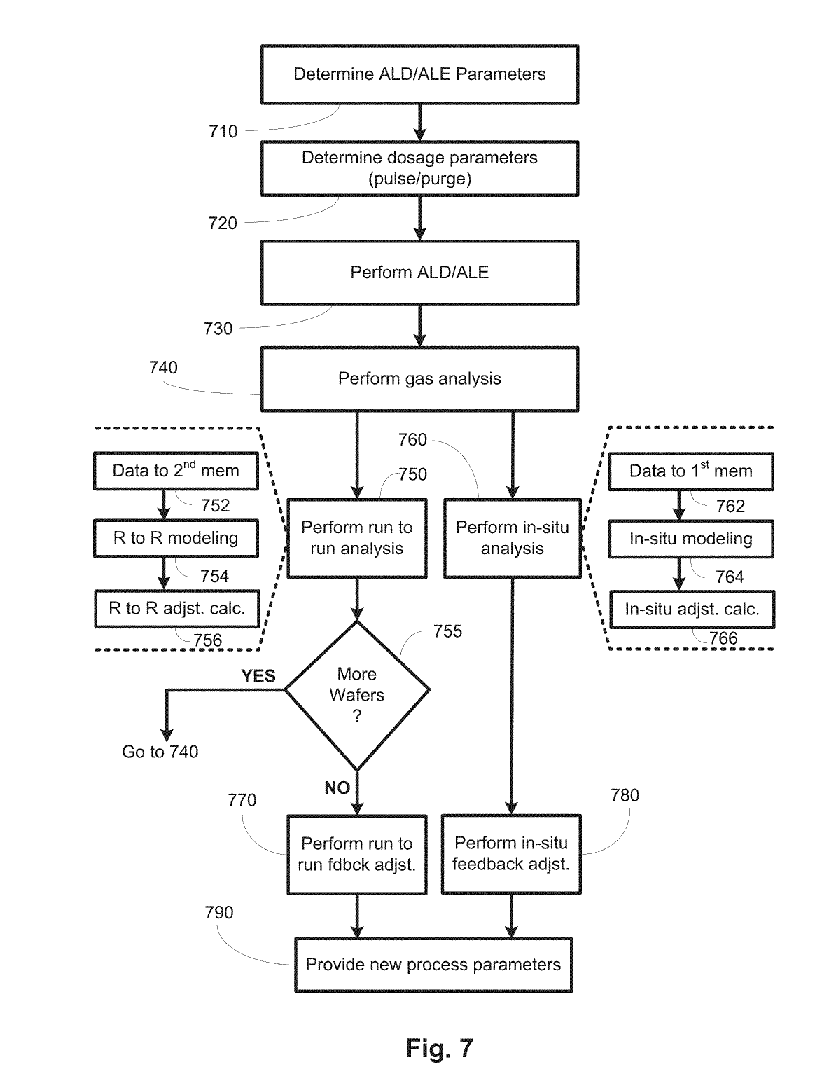

Turning now to FIG. 7, a stylized flowchart depiction of performing a wafer to wafer control of semiconductor wafer processing, in accordance with embodiments herein, is illustrated. Initial parameters for performing an ALD process or an ALE process are determined (at 710). These parameters may include vessel temperature, reactor operating voltage, precursor chemical type, etc.

Further, initial dosage parameters, precursor pulse cycles and precursor purge cycles may be determined (at 720). Based upon the process parameters, an ALD process or an ALE process may be performed (at 730). Upon performing the ALD/ALE process, a gas analysis process may be performed (at 740). The gas analysis process may comprise acquiring exhaust post process data relating to residual gas, exhaust gas, and of leftover precursor gas, and performing an analysis process (e.g., spectroscopy analysis).

Upon performing the gas analysis, a run to run analysis (at 740) and an in-situ analysis (at 750) may be performed. The run to run analysis may comprise providing gas analysis data to a 2^{nd} memory (at 752). Data from the 2^{nd} memory may be used to perform a run to run modeling (at 754). The run to run modeling may comprise summing spectral intensity data for a plurality of wafers and determining a film thickness growth rate. This information may then be used to adjust one or more process parameters (at 756) (e.g., vessel temperature, precursor pulse time, precursor purge time, etc.). A determination is made if additional wafers remain to analyze in a run (at 755). If an additional wafer in the run remains, that wafer is then processed. If additional wafer are not present in the run, then a feedback adjustment (run to run) may be performed (at 770).

The wafer to wafer analysis may comprise providing gas analysis data to a 1^{st} memory (at 762). Data from the 1^{st} memory may be used to perform a wafer to wafer modeling (at 764). The wafer to wafer modeling may comprise deterring spectral intensity data for each wafer and obtaining a film thickness. This information may then be used to adjust one or more process parameters (at 766) (e.g., vessel temperature, precursor pulse time, precursor purge time, etc.) between processing of each wafer in a run. Upon performing the in-situ analysis, a wafer to wafer feedback process may be performed (at 780). Based upon the feedback adjustments, updated process parameters are provided and subsequent processing steps are performed (at 790). As such, using a gas analysis scheme, wafer to wafer feedback adjustments as well as run to run feedback adjustments may be made when performing semiconductor wafer processing (e.g., ALD or ALE processes).

The system described above may be capable of performing analysis and manufacturing of various products involving various technologies. For example, the systems herein may design and manufacturing-data for manufacturing devices of CMOS technology, Flash technology, BiCMOS technology, power devices, memory devices (e.g., DRAM devices), NAND memory devices, and/or various other semiconductor technologies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
performing a first process on a first semiconductor wafer of a run of semiconductor wafers using a processing tool;
performing a first gas analysis of a gas in said processing tool based upon performing said first process;
determining, based upon a result of said first gas analysis, a process feedback adjustment;
providing data relating to said process feedback adjustment, wherein said process feedback adjustment is a wafer to wafer feedback process adjustment; and
performing, based on said data relating to said process feedback adjustment, a second process on a second semiconductor wafer of said run of wafers.

2. (canceled)

3. The method of claim 1, further comprising:
performing a second gas analysis of a gas in said processing tool upon performing said second process;
aggregating a result of the first gas analysis and a result of the second gas analysis;
determining, based on the aggregating, data relating to a run to run feedback adjustment; and
providing said data relating to the run to run feedback process adjustment.

4. The method of claim 3, wherein determining a process feedback adjustment comprises at least one of:
performing a first modeling of said first process based on said result of said gas analysis for performing a wafer to wafer feedback adjustment; or
performing a second modeling of said first and second processes based on said results of said first and second gas analyses for performing a run to run feedback adjustment.

5. The method of claim 3, further comprising performing a prediction of a film growth rate to determine a run to run feedback adjustment.

6. The method of claim 3, determining, based on the aggregating, data relating to a run to run feedback adjustment comprises determining the sum of all measured linear atomic mass unit intensities.

7. The method of claim 3, wherein:
performing said first gas analysis of a gas in said processing tool comprises performing said first gas analysis on at least one of an exhaust resulting from said first process, or on a residue of a first precursor used to perform said first process; and
performing said second gas analysis of a gas in said processing tool comprises performing said second gas analysis on at least one of an exhaust resulting from said second process, or on a residue of a second precursor used to perform said second process.

8. The method of claim 1, wherein performing the first process on said first semiconductor substrate using a processing tool comprises:
providing a first precursor during a time period defined by a first precursor pulse of a signal;
performing a first purge of gas in said processing tool during a time period defined by a first purge portion of said signal;
providing a second precursor during a time period defined by a second precursor pulse of a signal; and
performing a second purge of gas in said processing tool during a time period defined by a second purge portion of said signal.

9. The method of claim 1, wherein performing the first process on a first semiconductor substrate using a processing tool comprises performing at least one an atomic layer deposition (ALD) process, or an atomic layer etch (ALE) process.

10. The method of claim 1, wherein determining a feedback adjustment comprises at least one of:
changing the number of precursor cycles;
changing the temperature of a precursor; or
performing a look-up in a calibration look-up table to determine a gas dosage based on a linear intensity based on the gas analysis.

11. A method, comprising:
performing a first atomic layer process on a first semiconductor wafer of a run of wafers using an atomic layer process tool and a first precursor;
performing a first gas analysis of at least one of an exhaust gas or a residue of said first precursor from said atomic layer process tool upon performing said atomic layer process;
determining, based upon a result of said first gas analysis, a feedback adjustment for processing a second semiconductor wafer;
providing data relating to said result of said first gas analysis to a first process model for determining a precursor pulse parameter and a precursor purge parameter feedback adjustment, wherein said parameter feedback adjustment is a wafer to wafer parameter feedback adjustment; and
performing, based on said precursor pulse parameter and a precursor purge parameter feedback adjustment, a second atomic layer process on a second semiconductor wafer of said run of wafers.

12. The method of claim 11, wherein determining said precursor pulse and precursor purge parameters comprises determining at least one of a number of pulse and purge cycles, a temperature of a vessel holding the first precursor, or a pulse time period and a purge time period.

13. The method of claim 11, further comprising:
performing a second gas analysis of at least one of an exhaust of a residue of said first precursor in said atomic layer process tool upon performing said second atomic layer process;
aggregating said result of the first gas analysis and a result of the second gas analysis;
determining, based on the aggregating, data relating to a run to run feedback adjustment using a second process model; and
providing said data relating to the run to run feedback process adjustment.

14. The method of claim 13, further comprising performing a prediction of a film growth rate based upon said aggregating to determine said run to run feedback adjustment.

15. The method of claim 11, wherein performing said atomic layer process comprises performing at least one of an atomic layer deposition (ALD) process or an atomic layer etch (ALE) process.

16. A system, comprising:
a processing tool capable of performing a process on a first semiconductor wafer and on a second semiconductor wafer;
a first process controller operatively coupled to said processing tool;
a dose controller operatively coupled to said first process controller, said dose controller being capable of providing a plurality of dosage parameters to said process controller;
a gas analyzer capable of performing a first gas analysis on at least one of an exhaust gas or a residue gas from said processing tool relating to a first process performed on said first semiconductor substrate; and
a first process model capable of a first modeling of a process based on a result of said first gas analysis and providing a first feedback signal for performing a second process on said second semiconductor substrate based on said first modeling, wherein said first feedback signal is a wafer to wafer feedback signal.

17. The system of claim 16, further comprising a second process model, said second process model capable of receiving said result of a first gas analysis and a result of a second gas analysis of at least one of a exhaust or a residue relating to said second process and performing an aggregation of said results to determine a film growth rate for providing a second feedback signal for performing a run to run feedback control.

18. The system of claim 16, wherein providing said first and second feedback signals comprises at least one of:
a change in the number of precursor cycles for a precursor used by said processing tool;
a change in the temperature of the precursor; or
a gas dosage based on a linear intensity based on the gas analysis.

19. The system of claim 16, further comprising a second process controller, wherein said first process controller is capable of performing a wafer to wafer control and said second process controller is capable of performing a run to run control.

20. The system of claim 16, wherein said processing tool is one of an atomic layer deposition (ALD) tool or an atomic layer deposition etch (ALE) tool.
